(19) United States
(12) Patent Application Publication
(10) Pub. No.: US 2017/0081178 A1
(43) Pub. Date: Mar. 23, 2017

(54) SEMICONDUCTOR DEVICE PACKAGE WITH SEAL STRUCTURE

(71) Applicant: FREESCALE SEMICONDUCTOR, INC., AUSTIN, TX (US)

(72) Inventors: THOMAS C. SPEIGHT, CHANDLER, AZ (US); STEPHEN R. HOOPER, MESA, AZ (US); NHAT D. VO, AUSTIN, TX (US)

(21) Appl. No.: 14/860,976

(22) Filed: Sep. 22, 2015

(51) Int. Cl. B81B 7/00; B81C 1/00

(52) U.S. Cl. CPC B81B 7/0058; B81C 1/00301; B81B 2201/0264; B81B 2203/0127; B81B 2207/07; B81B 2207/094; B81B 2207/03; B81C 2201/0197; B81C 2203/0172; B81C 2203/035; B81C 2203/0792; B81C 2203/0145

(57) ABSTRACT

A packaged semiconductor device includes a first semiconductor die including interconnect pads and a seal ring pad surrounding at least some of the interconnect pads, a first portion of an plated seal ring structure formed on the seal ring pad, and a second semiconductor die including a second portion of the plated seal ring structure formed on a major surface of the second semiconductor die. The second portion of the plated seal ring structure is coupled to the first portion of the plated seal ring structure to form a seal around a cavity between the first and second semiconductor die. A plurality of interconnect pillars are on the first major surface of the second semiconductor die. The interconnect pillars are coupled to the interconnect pads on the second semiconductor die.

### BACKGROUND

Field

This disclosure relates generally to semiconductor device packaging, and more specifically, to a semiconductor device package having a seal structure.

Related Art

Semiconductor devices which include microelectromechanical systems (MEMS) are widely used in a variety of sensing applications. For example, a MEMS pressure sensor may be implemented on a semiconductor die to generate electrical signals indicative of the amount of pressure exerted on the semiconductor die (or a portion thereof). Often, these devices are packaged in a manner that provides protection from corrosive elements and helps ensure relatively high reliability over the lifetime of the device so that these devices may be used in harsh operating environments, such as, for example, in an automotive application. In an automotive application, a semiconductor device including a pressure sensor may be subjected to high pressure while within a pressurized tire, for example, allowing air bubbles to permeate portions of the packaged semiconductor device. However, in a rapid decompression event (RDE) such as a blowout of the pressurized tire, the bubbles can temporarily or permanently affect the operation semiconductor device.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIGS. 1-4 illustrate, in a simplified cross-sectional view, a packaged semiconductor device at various stages of manufacture in accordance with an embodiment of the present disclosure.

FIG. 5 illustrates, in a plan view form, the semiconductor device including a sensor, shown in FIG. 4, in accordance with an embodiment of the present disclosure.

### DETAILED DESCRIPTION

Generally, there is provided, a packaged semiconductor device that includes a first semiconductor die having a seal ring pad surrounding one or more interconnect pads and a second semiconductor die having a corresponding seal ring pad and one or more corresponding interconnect pads wherein the seal ring pad and corresponding seal ring pad are coupled to form an airtight or hermetic seal around a cavity between the first and second semiconductor die. The seal around the cavity can prevent air bubbles from permeating critical portions of the packaged semiconductor device allowing the packaged semiconductor device to operate normally after experiencing a rapid decompression event (RDE) such as a blowout of a pressurized tire.

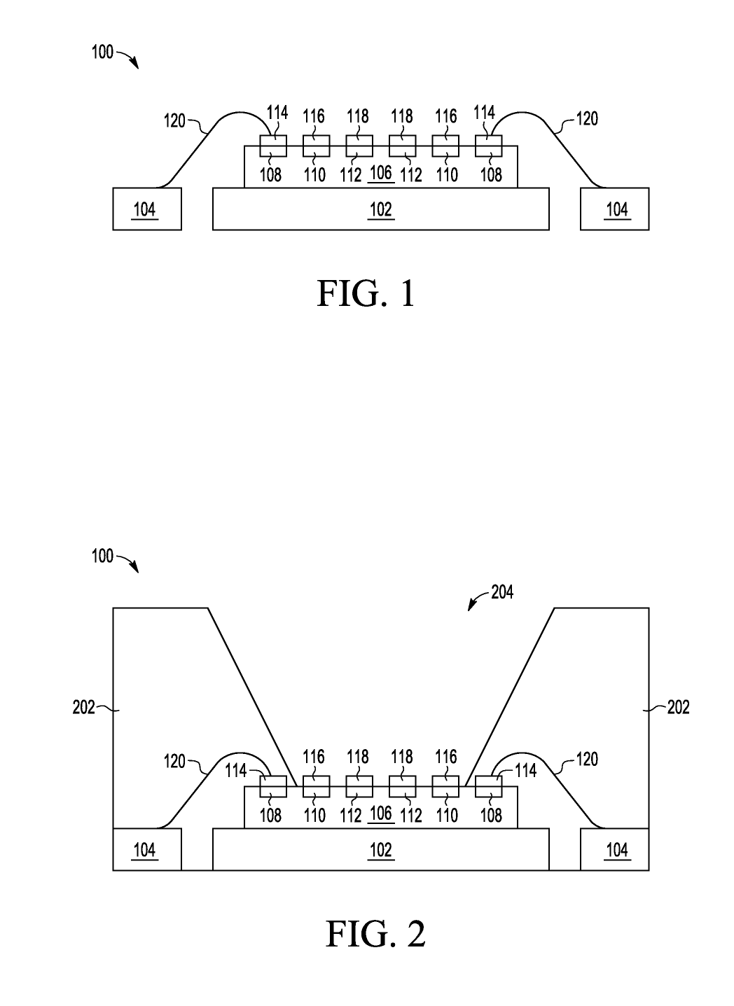

FIGS. 1-4 illustrate, in a simplified cross-sectional view, an exemplary packaged semiconductor device 100 at various stages of manufacture in accordance with an embodiment of the present disclosure.

FIG. 1 illustrates, in a simplified cross-sectional view, a stage of manufacture of packaged semiconductor device 100, including a leadframe and a first semiconductor die 106. The leadframe includes a flag 102 suitable for attachment of the first semiconductor die 106, and plurality of bond leads 104. The leadframe may be formed of any suitable electrically conductive material that is easy to shape, such as aluminum, copper, nickel, or iron, or alloys including one or more of these materials, such as alloy-42 for example. The conductive metal may be bare, partially plated, or plated with another metal or an alloy such as iron/nickel alloy, silver, gold, or the like. In some embodiments, the leadframe may be formed as conductive traces on a substrate such as ceramic or silicon, for example.

The flag 102 may be any shape, size, or configuration suitable for an attached semiconductor die. In some embodiments, the flag 102 may be characterized as a downset flag where the plane of the flag 102 is below the plane of the plurality of bond leads 104. The plurality of bond leads 104 couple electrical signals between locations at the outside of a finished semiconductor device package and locations within the package such as wirebond pad on the semiconductor die 106.

The first semiconductor die 106 is attached to the flag 102 with an adhesive (not shown). The adhesive may be a solder alloy, an epoxy, or any suitable die-attach material such as a die-attach film, for example. The first semiconductor die 106 includes a plurality of bond pads 108, interconnect pads 112, and a seal ring pad 110 located on the top major surface of the die. The bond pads 108, interconnect pads 112, and seal ring pad 110 may be formed during separate wafer processing steps. In some embodiments, the bond pads 108, interconnect pads 112, and seal ring pad 110 may be formed during common wafer processing steps. The bond pads 108, interconnect pads 112, and seal ring pad 110 may be formed of any suitable metal such as aluminum, copper, silver, nickel, or the like for example. Seal ring pad 110 forms a continuous ring enclosing a portion of the top major surface of the first semiconductor die 106. The continuous ring may be in the form of any closed shape such as a custom shape, square, rectangle, oval, and the like for example. One or more of interconnect pads 112 are located within the enclosed portion of the top major surface of the first semiconductor die 106. Bond pads 108, interconnect pads 112, and seal ring pad 110 are electroless plated in layers with suitable metal such as nickel, palladium, and gold, for example, to form plated bond pads 114, plated interconnect pads 118, and a first portion of a plated seal ring structure 116. First semiconductor die 106 may be formed of any semiconductive material, such as silicon, germanium, gallium arsenide, and the like. First semiconductor die 106 may include any or combination of digital circuits, analog circuits, memory, processor, MEMS, sensors, and the like.

Bond wires 120 electrically couple plated bond pads 114 on the first semiconductor die 106 to the plurality of bond leads 104 of the leadframe. The bond wires 120 may be formed of a metal comprising aluminum, copper, silver, or gold. The bond wires 120 may be attached to the first semiconductor die 106 and the leadframe bond leads 104 with either ball bonds or wedge bonds or a combination of ball bonds and wedge bonds. For example, ball bonds may be used to attach a first end of bond wires 120 to plated bond pads 114 of the first semiconductor die 106 and wedge bonds may be used to attach the opposite ends of bond wires 120 to the bond leads 104 of the leadframe.

FIG. 2 illustrates, in a simplified cross-sectional view form, a subsequent stage of manufacture of the exemplary packaged semiconductor device 100, including an encapsulant. A mold compound 202 encapsulates a portion of the first semiconductor die 106, bond wires 120, and a portion of the leadframe flag 102 and bond leads 104 to form a semiconductor device package having an opening 204 over a portion of the first semiconductor die 106. The semiconductor device package may be in the form of a quad flat no-lead (QFN) package, quad flat pack (QFP) package, small outline integrated circuit (SOIC) package, or the like. The encapsulant 202 may be any suitable mold compound such as a plastic mold compound or an epoxy mold compound, for example. The encapsulating process may include any suitable molding technique such as film-assisted molding (FAM), for example.

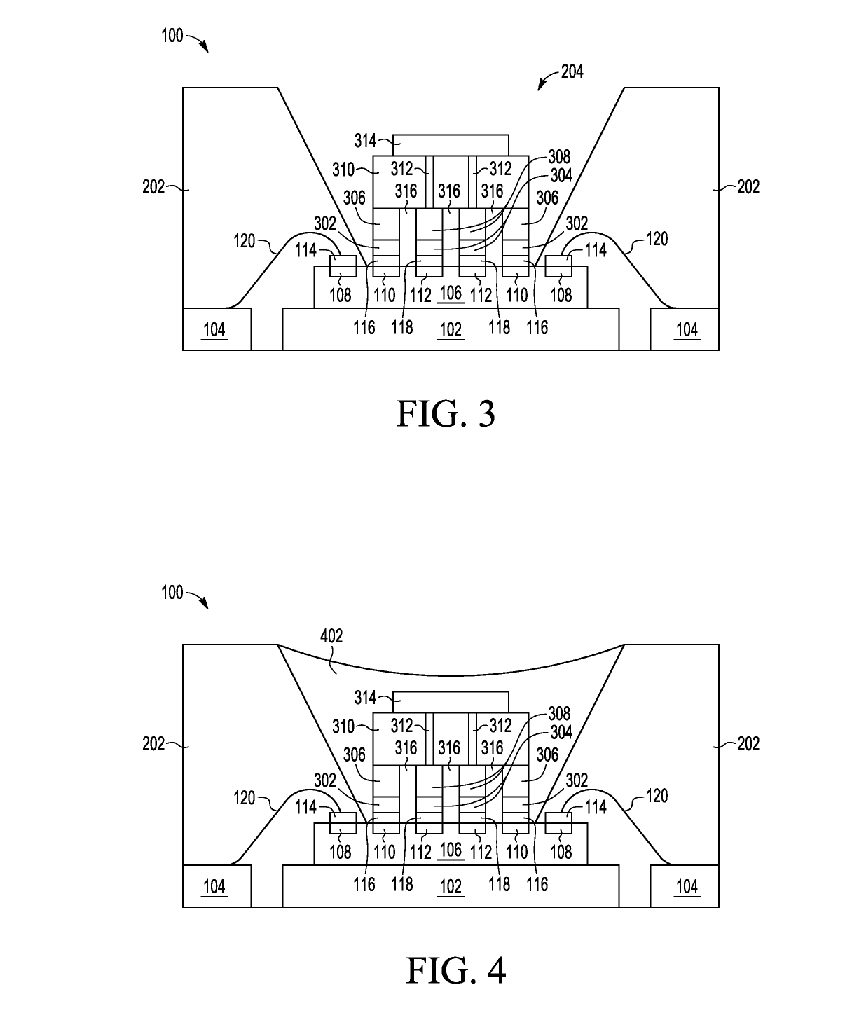

FIG. 3 illustrates, in a simplified cross-sectional view form, a subsequent stage of manufacture of the exemplary packaged semiconductor device 100, including a second semiconductor die 310. A second portion of a plated seal ring structure (302/306) and interconnect pillar (304/308) formed on the second semiconductor die 310 are used to couple the second semiconductor die 310 to the first semiconductor die 106. In this embodiment, the second semiconductor die 310 includes a MEMS pressure sensor (not shown) located on a first major surface of the die coupled to a diaphragm 314. Through-silicon vias (TSVs) or through hole vias 312 can be used to couple signals at the first major surface of the second semiconductor die 310 with a second major surface of the die. For example, TSVs may couple supplies and/or signals of a MEMS sensor located on the first major surface with pads on the second major surface for connectivity with another die. Interconnect pads (not shown) and seal ring pad (not shown) are formed on the second major surface of second semiconductor die 310. The interconnect bond pads and seal ring pad may be formed of any suitable metal such as aluminum, for example. In this embodiment, the interconnect pads and seal ring pad are electrolytic plated with copper to form a copper portion of the second portion of a plated seal ring 306 and a copper portion of the interconnect pillar structures 308. Solder (302 and 304) is plated or deposited on the copper portions 306 and 308 forming the second portion of the plated seal ring structure (302/306) and interconnect pillars (304/308), respectively. The solder may be any suitable material such as tin, for example. A layer of a barrier material may be formed onto the exposed copper portions before plating the solder layer. In some embodiments, the second portion of the plated seal ring structure (302/306) and interconnect pillars (304/308) may be used for attaching to and forming an electrical coupling with a substrate, semiconductor die, printed circuit board, or the like. In some embodiments, the second portion of the plated seal ring structure and the interconnect pillars may be formed with at least a portion consisting of copper, nickel, or silver.

The second portion of the plated seal ring structure (302/306) is coupled to the first portion of the plated seal ring structure 116 to form an airtight or hermetic seal ring around a cavity 316 between the first and second semiconductor die 106 and 310. The second semiconductor die 310 is coupled to the first semiconductor die 106 using a bonding process such as thermocompression bonding, thermosonic bonding, or reflowing the solder material, for example, whereby the interconnect pillars (304/308) and second portion of the plated seal ring (302/306) are bonded to corresponding plated pads 118 and the first portion of a plated seal ring structure 116 on the semiconductor die 106. The sealed cavity 316 may include air or a material such as a conductive compound, a non-conductive compound, or any combination of materials and air. In some embodiments, the second semiconductor die 310 may include a plurality of sensors. In some embodiments, the second semiconductor die 310 may be formed of any semiconductive material, such as silicon, germanium, gallium arsenide, and the like. Second semiconductor die 310 may include any or combination of digital circuits, analog circuits, memory, processor, MEMS, sensors, and the like.

FIG. 4 illustrates, in a simplified cross-sectional view form, a subsequent stage of manufacture of the exemplary packaged semiconductor device 100, including opening 204 filled with a material 402. After the second semiconductor die 310 is coupled to the first semiconductor die 106, a material 402 such as a gel, thermoplastic resin, epoxy, or the like may be deposited in the opening 204 around the second semiconductor die 310 and around exposed surfaces of the plated seal ring structure. The filled material 402 may serve to protect the first and second semiconductor die from environmental elements such as moisture, for example. In some embodiments, opening 204 may remain open having at least a portion of the second semiconductor die exposed.

In yet another subsequent stage of manufacture of the exemplary semiconductor device 100, a lid (not shown) may be attached to the top of the package to enclose the filled opening of FIG. 4. The lid may serve to further protect the first and second semiconductor die. The lid may include a small opening or hole to allow air to pass through it which is especially useful for enclosing a pressure sensor.

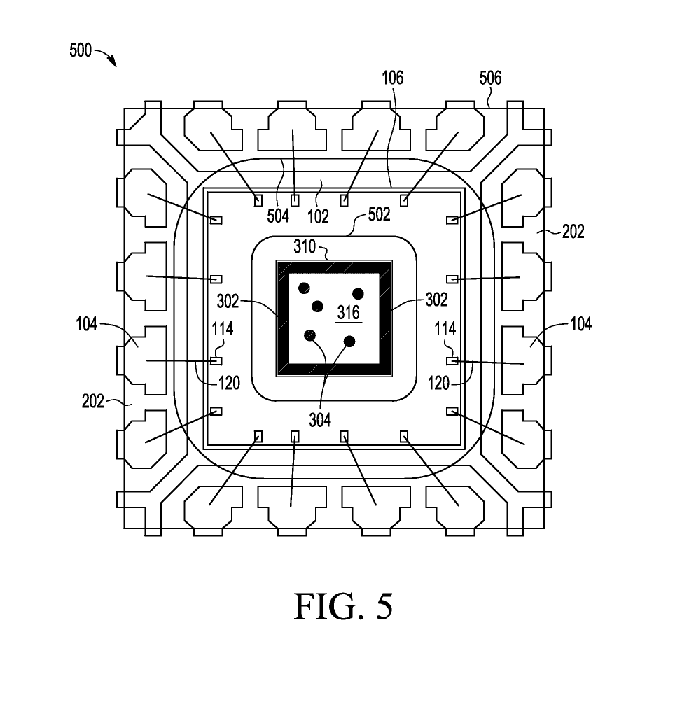

FIG. 5 illustrates, in plan view form, a packaged semiconductor device 500 including a second semiconductor die 310 coupled to a first semiconductor die 106 as illustrated in FIG. 4, in accordance with an embodiment of the present disclosure. The packaged semiconductor device 500 includes a leadframe, a first semiconductor die 106, and a second semiconductor die 310. The leadframe includes a flag 102 suitable for attachment of the first semiconductor die 106, and plurality of bond leads 104. The leadframe may be formed of any suitable electrically conductive material that is easy to shape, such as aluminum, copper, nickel, or iron, or alloys including one or more of these materials, such as alloy-42 for example. The conductive metal may be bare, partially plated, or plated with another metal or an alloy such as iron/nickel alloy, silver, gold, or the like.

The first semiconductor die 106 is attached to the flag 102 with an adhesive (not shown). The adhesive may be a solder alloy, an epoxy, or any suitable die-attach material such as a die-attach film, for example. The first semiconductor die 106 includes a plurality of bond pads, interconnect pads, and a seal ring pad located on the top major surface of the die. The bond pads, interconnect pads, and seal ring pad may be formed during separate wafer processing steps. In some embodiments, the bond pads, interconnect pads, and seal ring pad may be formed during common wafer processing steps. Bond pads, interconnect pads, and seal ring pad are electroless plated with suitable metal such as nickel, palladium, and gold, for example, to form plated bond pads 114, plated interconnect pads (not shown), and a first portion of a plated seal ring structure (not shown). First semiconductor die 106 may be formed of any semiconductive material, such as silicon, germanium, gallium arsenide, and the like. First semiconductor die 106 may include any or combination of digital circuits, analog circuits, memory, processor, MEMS, sensors, and the like.

Bond wires 120 electrically couple plated bond pads 114 on the first semiconductor die 106 to the plurality of bond leads 104 of the leadframe. The bond wires 120 may be formed of a metal comprising aluminum, copper, silver, or gold. The bond wires 120 may be attached to the first semiconductor die 106 and the leadframe bond leads 104 with either ball bonds or wedge bonds or a combination of ball bonds and wedge bonds. For example, ball bonds may be used to attach a first end of bond wires 120 to plated bond pads 114 of the first semiconductor die 106 and wedge bonds may be used to attach the opposite ends of bond wires 120 to the bond leads 104 of the leadframe.

A mold compound 202 encapsulates a portion of the first semiconductor die 106, bond wires 120, and a portion of the leadframe flag 102 and bond leads 104 to form a semiconductor device package having an opening over a portion of the first semiconductor die 106. In this embodiment, the encapsulant wall of the opening is tapered having a smaller opening portion 502 at the first semiconductor die 106 and a larger opening portion 504 at the top of the opening wall. An outer wall perimeter 506 of the encapsulant may be formed in the molding process or in a singulation process wherein the packaged semiconductor device is sawn, cut, or otherwise separated from a strip including a plurality of encapsulated semiconductor devices. The semiconductor device package may be in the form of a quad flat no-lead (QFN) package, quad flat pack (QFP) package, small outline integrated circuit (SOIC) package, or the like. The encapsulant 202 may be any suitable mold compound such as a plastic mold compound or an epoxy mold compound, for example. The encapsulating process may include any suitable molding technique such as film-assisted molding (FAM), for example.

A second portion of a plated seal ring structure 302 and interconnect pillar 304 formed on the second semiconductor die 310 are used to couple the second semiconductor die 310 to the first semiconductor die 106. In this embodiment, the second semiconductor die 310 includes a MEMS pressure sensor (not shown). Interconnect pads (not shown) and seal ring pad (not shown) are formed on a major surface of second semiconductor die 310. The interconnect bond pads and seal ring pad may be formed of any suitable metal such as aluminum, for example. In this embodiment, the interconnect pads and seal ring pad are plated with copper to form a copper portion of the second portion of a plated seal ring 306 and a copper portion of the interconnect pillar structures 308. Solder (302 and 304) is plated on the copper portions forming the second portion of the plated seal ring structure 302 and interconnect pillars 304, respectively. The second portion of the plated seal ring structure 302 is coupled to the first portion of the plated seal ring structure (not shown) to form a seal around a cavity 316 between the first and second semiconductor die 106 and 310. The second semiconductor die 310 is coupled to the first semiconductor die 106 using a bonding process such as thermocompression bonding or thermosonic bonding, for example, whereby the interconnect pillars 304 and second portion of the plated seal ring 302 are bonded to corresponding plated pads and the first portion of a plated seal ring structure on the first semiconductor die 106. The second semiconductor die 310 may be formed of any semiconductive material, such as silicon, germanium, gallium arsenide, and the like. Second semiconductor die 310 may include any or combination of digital circuits, analog circuits, memory, processor, MEMS, sensors, and the like.

After the second semiconductor die 310 is coupled to the first semiconductor die 106, the opening may be filled with a material such as a gel, thermoplastic resin, epoxy, or the like. The filled material may serve to protect the first and second semiconductor die from environmental elements such as moisture, for example. In some embodiments, opening may remain open having at least a portion of the second semiconductor die exposed. In some embodiments, a lid (not shown) may be attached to the top of the package to enclose the filled opening. The lid may serve to further protect the first and second semiconductor die. The lid may include a small opening or hole to allow air to pass through it which is especially useful for enclosing a pressure sensor.

By now, it should be appreciated that a packaged semiconductor device has been provided that includes a first semiconductor die having a seal ring pad surrounding one or more interconnect pads and a second semiconductor die having a corresponding seal ring pad and one or more corresponding interconnect pads wherein the seal ring pad and corresponding seal ring pad are coupled to form an airtight or hermetic seal around a cavity between the first and second semiconductor die. The seal around the cavity can prevent air bubbles from permeating critical portions of the packaged semiconductor device.

Generally, there is provided, a packaged semiconductor device including: a first semiconductor die including interconnect pads and a seal ring pad surrounding at least some of the interconnect pads; a first portion of a plated seal ring structure formed on the seal ring pad; and a second semiconductor die including: a second portion of the plated seal ring structure formed on a major surface of the second semiconductor die, wherein the second portion of the plated seal ring structure is coupled to the first portion of the plated seal ring structure to form a seal around a cavity between the first and second semiconductor die; a plurality of interconnect pillars on the first major surface of the second semiconductor die, wherein the interconnect pillars are coupled to the interconnect pads on the second semiconductor die. The packaged semiconductor device may further include a lead frame including bond leads; bond pads on the semiconductor die; plated pads on the bond pads, wherein the plated pads are formed of the same material as the first portion of the plated seal ring structure; and wire bonds between the plated pads on the first semiconductor die and the bond leads on the lead frame. The packaged semiconductor device may further include solder material coupling the first portion of the plated seal ring structure to the second portion of the plated seal ring structure. The second semiconductor die may be a pressure sensor including a diaphragm; and through hole vias formed in the pressure sensor between the interconnect pillars and the diaphragm. The packaged semiconductor device may further include encapsulant around the wire bonds; and gel around the second semiconductor die and the plated seal ring structure. The first portion of the plated seal ring structure and the plated bond pads on the first semiconductor die may be formed of layers of nickel, palladium, and gold. The interconnect pillars may be formed of at least one of a group consisting of: copper, nickel, and silver. The seal around the cavity may be at least one of a group consisting of a hermetic seal and an airtight seal. The cavity may be filled with at least one of a group consisting of air, conductive compound, and a non-conductive compound. The solder material may include tin and the interconnect pillars may include a layer of barrier material between the solder material and the interconnect pillars.

In another embodiment, there is provided, a method including: electroless plating a first portion of a continuous enclosure and a plurality of interconnect pads on a surface of a first semiconductor die, wherein the plurality of interconnect pads are surrounded by the first portion of the continuous enclosure, and the plurality of interconnect pads and the first portion of the continuous enclosure are formed of a first material; electrolytic plating a second portion of the continuous enclosure and a plurality of interconnect pillars on a surface of a second semiconductor die, wherein the second portion of the continuous enclosure and the interconnect pillars are formed of a second material; coupling the plurality of interconnect pads to respective ones of the interconnect pillars while coupling the first portion of the continuous enclosure to the second portion of the continuous enclosure, wherein after the coupling, the first and second portions of the continuous enclosure form a seal around a cavity between the first and second semiconductor die. The method may further include electroless plating wire bond pads on the first semiconductor die while electroless plating the first portion of the continuous enclosure and the plurality of interconnect pads on the surface of the first semiconductor die; and forming wire bonds between the wire bond pads and corresponding bond leads on a lead frame. The method may further include encapsulating the wire bonds; and depositing gel around the second semiconductor die and around an exposed surface of the continuous enclosure. The second semiconductor die may be a pressure sensor, the pressure sensor may include: a diaphragm; and through hole vias formed in the pressure sensor between the interconnect pillars and the diaphragm. The method may further include forming a layer of barrier material over an exposed end of the interconnect pillars. The coupling the plurality of interconnect pads to respective ones of the interconnect pillars while coupling the first portion of the continuous enclosure to the second portion of the continuous enclosure may include depositing solder material to the interconnect pillars and/or the interconnect pads; depositing solder material to the first and/or second portion of the continuous enclosure; and reflowing the solder material. The first portion of the plated seal ring structure and the bond pads on the first semiconductor die may be formed of layers of nickel, palladium, and gold. The interconnect pillars may be formed of at least one of a group consisting of: copper, nickel, and silver. The seal around the cavity may be at least one of a group consisting of: a hermetic seal and an airtight seal. The cavity may be filled with at least one of a group consisting of: air, conductive compound, and a non-conductive compound.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A packaged semiconductor device, comprising:
a first semiconductor die including interconnect pads and a seal ring pad surrounding at least some of the interconnect pads;
a first portion of a plated seal ring structure formed on the seal ring pad; and
a second semiconductor die including:
a second portion of the plated seal ring structure formed on a major surface of the second semiconductor die, wherein the second portion of the plated seal ring structure is coupled to the first portion of the plated seal ring structure to form a seal around a cavity between the first and second semiconductor die;
a plurality of interconnect pillars on the first major surface of the second semiconductor die, wherein the interconnect pillars are coupled to the interconnect pads on the second semiconductor die.

2. The packaged semiconductor device of claim 1, further comprising:
a lead frame including bond leads;
bond pads on the semiconductor die;
plated pads on the bond pads, wherein the plated pads are formed of the same material as the first portion of the plated seal ring structure; and
wire bonds between the plated pads on the first semiconductor die and the bond leads on the lead frame.

3. The packaged semiconductor device of claim 1, further comprising:
solder material coupling the first portion of the plated seal ring structure to the second portion of the plated seal ring structure.

4. The packaged semiconductor device of claim 1, wherein the second semiconductor die is a pressure sensor, the pressure sensor includes:
a diaphragm; and
through hole vias formed in the pressure sensor between the interconnect pillars and the diaphragm.

5. The packaged semiconductor device of claim 2, further comprising:
encapsulant around the wire bonds; and
gel around the second semiconductor die and the plated seal ring structure.

6. The packaged semiconductor device of claim 2, wherein the first portion of the plated seal ring structure and the plated bond pads on the first semiconductor die are formed of layers of nickel, palladium, and gold.

7. The packaged semiconductor device of claim 1, wherein the interconnect pillars are formed of at least one of a group consisting of: copper, nickel, and silver.

8. The packaged semiconductor device of claim 1, wherein the seal around the cavity is at least one of a group consisting of: a hermetic seal and an airtight seal.

9. The packaged semiconductor device of claim 1, wherein the cavity is filled with at least one of a group consisting of: air, conductive compound, and a non-conductive compound.

10. The packaged semiconductor device of claim 3, wherein the solder material includes tin and the interconnect pillars include a layer of barrier material between the solder material and the interconnect pillars.

11. A method comprising:
electroless plating a first portion of a continuous enclosure and a plurality of interconnect pads on a surface of a first semiconductor die, wherein the plurality of interconnect pads are surrounded by the first portion of the continuous enclosure, and the plurality of interconnect pads and the first portion of the continuous enclosure are formed of a first material;
electrolytic plating a second portion of the continuous enclosure and a plurality of interconnect pillars on a surface of a second semiconductor die, wherein the second portion of the continuous enclosure and the interconnect pillars are formed of a second material; and
coupling the plurality of interconnect pads to respective ones of the interconnect pillars while coupling the first portion of the continuous enclosure to the second portion of the continuous enclosure, wherein after the coupling, the first and second portions of the continuous enclosure form a seal around a cavity between the first and second semiconductor die.

12. The method of claim 11, further comprising:
electroless plating wire bond pads on the first semiconductor die while electroless plating the first portion of the continuous enclosure and the plurality of interconnect pads on the surface of the first semiconductor die; and
forming wire bonds between the wire bond pads and corresponding bond leads on a lead frame.

13. The method of claim 12, further comprising:
encapsulating the wire bonds; and
depositing gel around the second semiconductor die and around an exposed surface of the continuous enclosure.

14. The method of claim 12, wherein the second semiconductor die is a pressure sensor, the pressure sensor includes:
a diaphragm; and
through hole vias formed in the pressure sensor between the interconnect pillars and the diaphragm.

15. The method of claim 11, further comprising:
forming a layer of barrier material over an exposed end of the interconnect pillars.

16. The method of claim 11, wherein the coupling the plurality of interconnect pads to respective ones of the interconnect pillars while coupling the first portion of the continuous enclosure to the second portion of the continuous enclosure includes
depositing solder material to the interconnect pillars and/or the interconnect pads;
depositing solder material to the first and/or second portion of the continuous enclosure; and
reflowing the solder material.

17. The method of claim 11, wherein the first portion of the plated seal ring structure and the bond pads on the first semiconductor die are formed of layers of nickel, palladium, and gold.

18. The method of claim 11, wherein the interconnect pillars are formed of at least one of a group consisting of: copper, nickel, and silver.

19. The method of claim 11, wherein the seal around the cavity is at least one of a group consisting of: a hermetic seal and an airtight seal.

20. The method of claim 11, wherein the cavity is filled with at least one of a group consisting of: air, conductive compound, and a non-conductive compound.
